(19) United States
(12) Patent Application Publication
(10) Pub. No.: US 2026/0123414 A1
(43) Pub. Date: Apr. 30, 2026

(54) PACKAGE STRUCTURE INCLUDING COMPOSITE THERMAL INTERFACE MATERIAL LAYER AND METHODS OF FORMING THE SAME

(71) Applicant: Taiwan Semiconductor Manufacturing Company Limited, Hsinchu (TW)

(72) Inventors: Kathy YAN, Hsinchu (TW); Kuo-Chin CHANG, Chiayi City (TW); Chi-Shiang CHIOU, Hsinchu (TW); Chang-Jung HSUEH, Taipei (TW); Yu-Shiou TSAI, Tainan City (TW)

(21) Appl. No.: 18/929,932

(22) Filed: Oct. 29, 2024

(51) Int. Cl. H01L 23/373; H01L 21/56; H01L 23/00; H01L 23/31; H01L 23/367

(52) U.S. Cl. CPC H10W 40/251; H10W 40/22; H10W 40/255; H10W 74/01; H10W 72/073; H10W 72/07354; H10W 72/325; H10W 72/347; H10W 72/353; H10W 72/354; H10W 74/111; H10W 90/734

(57) ABSTRACT

A package structure includes a package substrate, a semiconductor module on the package substrate, a composite thermal interface material (TIM) layer including liquid metal in a polymer matrix on the semiconductor module, a package lid on the composite TIM layer and attached to the package substrate, and a reactive interface layer in contact with the composite TIM layer on at least one of the semiconductor module or the package lid.

### BACKGROUND

A semiconductor package (package structure) may include a metal thermal interface material (TIM) layer to enhance heat transfer between semiconductor dies and a heat sink or other cooling component. The metal TIM layer may help to maintain a semiconductor package's performance and reliability by ensuring efficient heat dissipation.

The metal TIM layer may include a variety of different types of metal TIMs. The type of metal TIM used by a designer may be chosen based on factors like thermal conductivity, ease of application, operating temperature range, and compatibility with other materials in the semiconductor package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to one or more embodiments.

FIG. 1B is a detailed vertical cross-sectional view of Region B of the package structure in FIG. 1A according to one or more embodiments.

FIG. 1C is a detailed vertical cross-sectional view of Region C of the package structure in FIG. 1A according to one or more embodiments.

FIG. 1D is a detailed vertical cross-sectional view of Region D of the package structure in FIG. 1A according to one or more embodiments.

FIG. 2 is a schematic drawing of a composite TIM layer in the package structure, according to one or more embodiments.

FIG. 3 is a top-down view of the package structure according to one or more embodiments.

FIG. 4 is a top-down view of the package lid plate portion according to one or more embodiments.

FIG. 5A is a vertical cross-sectional view of an intermediate structure including the package substrate having package substrate upper bonding pads and package substrate lower bonding pads, according to one or more embodiments.

FIG. 5B illustrates a vertical cross-sectional view of an intermediate structure in which the semiconductor module may be mounted on the package substrate according to one or more embodiments.

FIG. 5C illustrates a vertical cross-sectional view of an intermediate structure in which the package underfill layer may be formed on the package substrate according to one or more embodiments.

FIG. 5D illustrates a vertical cross-sectional view of an intermediate structure in which the surface mount devices (SMDs) may be mounted on the package substrate according to one or more embodiments.

FIG. 5E illustrates a vertical cross-sectional view of an intermediate structure in which the composite thermal interface material (TIM) layer may be formed on the semiconductor module according to one or more embodiments.

FIG. 5F illustrates a vertical cross-sectional view of an intermediate structure after applying the sealant and adhesive layer according to one or more embodiments.

FIG. 5G illustrates a vertical cross-sectional view of an intermediate structure in which the package lid may be attached to (e.g., mounted on) the package substrate according to one or more embodiments.

FIG. 5H illustrates a vertical cross-sectional view of an intermediate structure in which the BGA including a plurality of solder balls may be formed on the package substrate according to one or more embodiments.

FIG. 6 is a flow chart illustrating a method of forming the package structure according to one or more embodiments.

FIG. 7 is a vertical cross-sectional view of a package structure having a first alternative design, according to one or more embodiments.

FIG. 8 is a vertical cross-sectional view of a package structure having a second alternative design, according to one or more embodiments.

FIG. 9 is a vertical cross-sectional view of a package structure having a third alternative design, according to one or more embodiments.

FIG. 10 is a vertical cross-sectional view of a package structure having a fourth alternative design, according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

A metal thermal interface material (TIM) layer may include, for example, a solder material, a phase-change metal material, a metallic foil, a metallic particle-filled material or a liquid metal material. The solder material may include, for example, indium, a tin-silver alloy or a tin-bismuth alloy. Indium has a high thermal conductivity and relatively low melting point which may help with forming a reliable bond between components. The tin-silver alloy has good thermal and electrical conductivity making tin-silver alloy useful for electronics applications. The tin-silver alloy is also lead-free, which may be desirable for compliance with environmental regulations. The tin-bismuth alloy has a low melting point and may be used in applications where minimal thermal stress on components is required.

A phase-change metal material (metallic phase-change material) may start in a solid state but transition to a liquid phase at certain temperatures, filling in gaps and reducing thermal resistance when heated. The phase-change metal material may include, for example, alloys with low melting points such as bismuth-based alloys or indium-based alloys.

A metallic foil may include, for example, indium foils or silver foils. Indium foils may offer good thermal conductivity and may conform to irregular surfaces under pressure. Silver foils are highly thermally conductive and may be used in high-performance applications.

Metallic particle-filled TIMs may include, for example, a paste filled with metal particles such as silver or aluminum. The particles may enhance thermal conductivity while the paste ensures good contact with the surfaces.

Of the various types of metal TIMs, liquid metal TIMs are especially attractive for use in semiconductor package structures. Gallium is the primary component in most liquid metal TIMs. Gallium has a low melting point (around 29.8° C. or 85.6° F.) and excellent thermal conductivity. Gallium's ability to stay liquid at room temperature makes it a key ingredient in liquid metal TIMs. This may help gallium to conform closely to surfaces and fill in micro-gaps for excellent thermal transfer. Indium is often combined with gallium to form alloys that improve the overall properties of the liquid metal TIM. Indium may lower the melting point of the alloy and enhance indium's wettability. The wettability characteristic promotes the liquid metal TIM ability to spread evenly across surfaces. Tin is another common component in liquid metal TIMs. Tin may further lower the melting point of the alloy and improve the mechanical properties of the material. Tin may also contribute to the alloy's ability to wet and bond with various surfaces, such as copper and aluminum. A common liquid metal TIM formulation is a gallium-indium-tin alloy, (often referred to as Galinstan) which typically consists of about 68-69% gallium, 21-22% indium, and 9-10% tin.

Liquid metal TIMs may include other metals in addition to gallium, indium and tin. In particular, zinc may be added to adjust melting point and thermal properties. Bismuth may also be added to alter the mechanical and thermal characteristics. Silver is occasionally added in trace amounts to enhance thermal conductivity.

However, there may be a problem with liquid metal TIMs in that liquid metal TIMs are prone to oxidation. In particular, the gallium in liquid metal TIMs may be oxidized in an oxygen-containing environment. Gallium oxidation may cause poor interface adhesion during reliability torture testing.

An embodiment of the present disclosure may include a liquid metal TIM design that may mitigate the level of oxidation and improve interposer package reliability. In particular, an embodiment may include a composite TIM (e.g., liquid metal composite TIM). At least one embodiment may include a liquid metal composite in a polymer matrix, reactive interface layer, and a peripheral sealant design to enhance reliability.

At least one embodiment may include a package structure including a semiconductor module and surface mount devices (SMDs) on a package substrate. The semiconductor module may include an interposer, plural dies including a system on chip (SoC) die and a high bandwidth memory (HBM) die on the interposer, and a molding layer around plural dies. The semiconductor module may be attached to the package substrate by C4 bumps and underfill material may be formed on the package substrate around the C4 bumps. A TIM layer may be placed on the semiconductor module and a sealant may be formed around the TIM layer and the semiconductor module. A ball grid array (BGA) including a plurality of solder balls may be formed on the package substrate.

In at least one embodiment, the TIM layer may include a liquid metal composite with a polymer matrix. The package structure may also include a reactive interface layer to enhance TIM adhesion and reliability. In at least one embodiment, the TIM layer may be composed of a liquid metal composite including a gallium-based strip filler, ZnOx granular filler, and polymer matrix, and the reactive interface layer may include a gallium/indium/nickel reactive interface layer on the package lid and the semiconductor module. The total TIM layer bond line thickness (BLT) may be equal to a thickness (T1) of the first reactive interface layer on the semiconductor module plus a thickness (T2) of the composite TIM layer plus a thickness (T3) of the second reactive interface layer on the package lid. In at least one embodiment, T1+T3≤70% of the TIM layer BLT.

In at least one embodiment, on a side of the package lid, a width (W1) of the package lid-side sealant footage may be greater than a width (W1OH) of an over-head sealant footage. Further, a height (H1) of a step portion on a bottom surface of the package lid (underlying structure) may be less than a height (H1OH) of the over-head sealant.

In at least one embodiment, on a side of the package substrate the sealant may be located on the underfill material. A width (W2) of the substrate-side sealant footage may be less than or equal to a width (FW) of an outer portion of the underfill material. The width (W2) of the substrate-side sealant footage may also be less than or equal to the width (W1) of the package lid-side sealant footage.

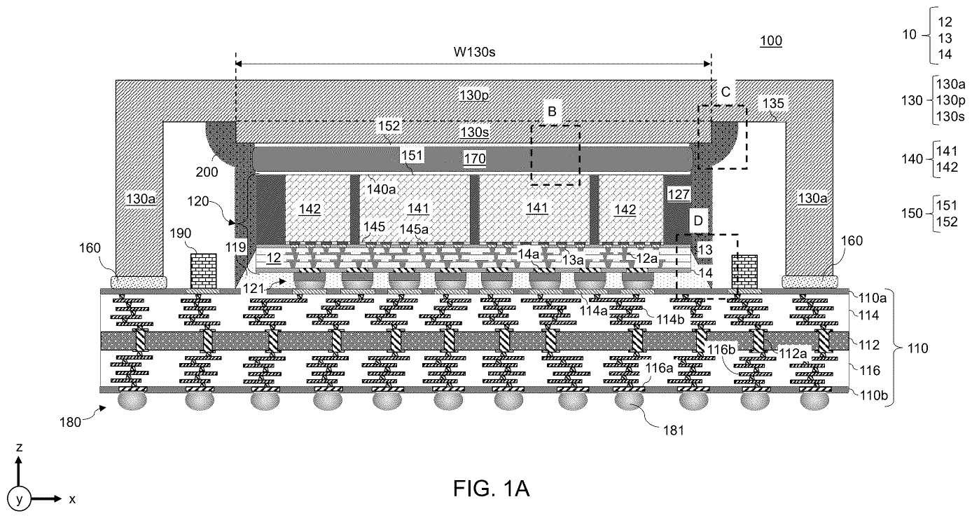

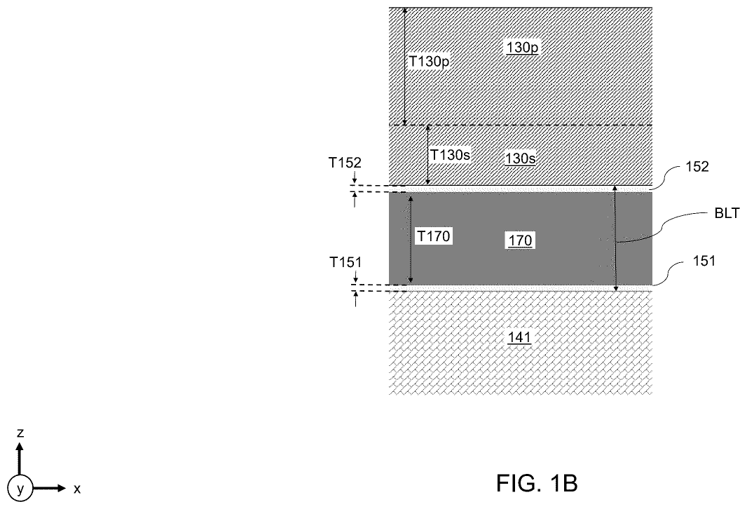

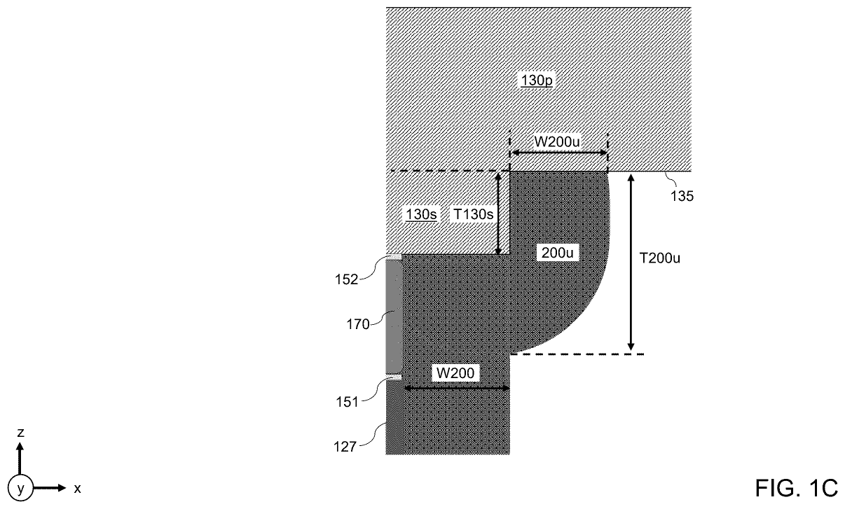

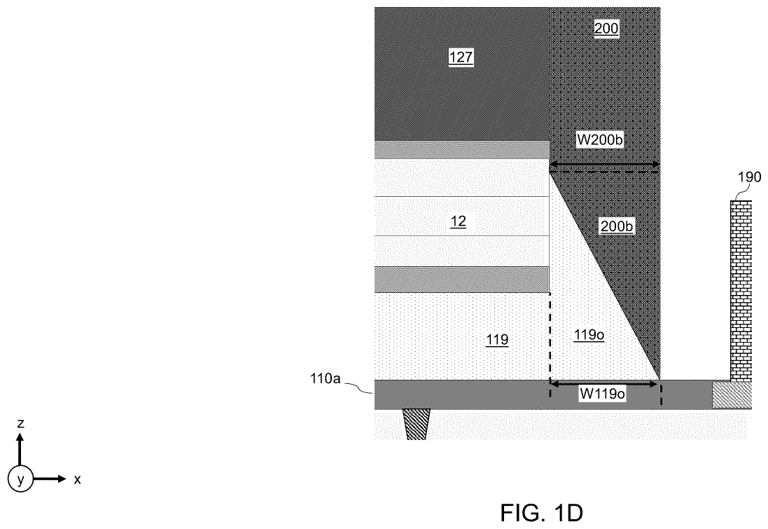

FIG. 1A is a vertical cross-sectional view of a package structure 100 according to one or more embodiments. FIG. 1B is a detailed vertical cross-sectional view of Region B of the package structure 100 in FIG. 1A according to one or more embodiments. FIG. 1C is a detailed vertical cross-sectional view of Region C of the package structure 100 in FIG. 1A according to one or more embodiments. FIG. 1D is a detailed vertical cross-sectional view of Region D of the package structure 100 in FIG. 1A according to one or more embodiments.

As illustrated in FIG. 1A, the package structure 100 may include a package substrate 110, a semiconductor module 120 on the package substrate 110, a composite TIM layer 170 including liquid metal in a polymer matrix on the semiconductor module 120 and a package lid 130 on the composite TIM layer 170 and attached to the package substrate 110. The package structure 100 may also include a reactive interface layer 150 in contact with the composite TIM layer 170 on at least one of the semiconductor module 120 or the package lid 130.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The metal interconnect structures 114b may constitute a redistribution layer (RDL) structure. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include a package substrate upper passivation layer 110a on the chip-side surface of the package substrate upper dielectric layer 114. The package substrate upper passivation layer 110a may partially cover the package substrate upper bonding pads 114a. The upper passivation layer 114a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The metal interconnect structures 114b may constitute a redistribution layer (RDL) structure. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate 110 may also include a package substrate lower passivation layer 110b on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

The package structure 100 may also include a ball-grid array (BGA) 180 including a plurality of solder balls 181 formed on the board-side surface of the package substrate lower dielectric layer 116. The solder balls 181 may allow the package structure 100 to be securely mounted on a substrate such as a printed circuit board (PCB) and electrically coupled to the PCB substrate. The solder balls 181 may contact the package substrate lower bonding pads 116a, respectively. The solder balls 181 may therefore be electrically connected to the package substrate upper bonding pads 114a by way of metal interconnect structures 116b, the through vias 112a and the metal interconnect structures 114b.

The semiconductor module 120 may include an interposer 10 and one or more semiconductor dies 140 (141, 142) on the interposer 10. The semiconductor module 120 is not limited to any particular configuration. The semiconductor module 120 may include, for example, a flip chip-chip scale package (FC-CSP) design, a chip-on-wafer-on-substrate (CoWoS®) design, an integrated fan-out (InFO_oS) design, and so on. In at least one embodiment, the interposer 10 may be omitted from the semiconductor module 120, in which case the semiconductor dies 140 may be attached directly to the package substrate 110.

The semiconductor module 120 may be bonded to and electrically coupled to the package substrate 110 by the C4 bumps 121 on the board-side surface of the interposer 10. In particular, the C4 bumps 121 may be formed on lower bonding pads 14a on a board-side surface of the interposer 10, respectively. The C4 bumps 121 may be bonded to the package substrate upper bonding pads 114a of the package substrate 110 using solder reflow, compression bonding, thermocompression bonding, etc. In at least one embodiment, the C4 bumps 121 may include underbump metallurgy (UBM) layers on the lower bonding pads 14a and the package substrate upper bonding pads 114a. The C4 bumps 121 may further include a contact pad (e.g., copper/nickel contact pad) on the UBM layers and a solder bump (e.g., SnAg solder bump) on the contact pad.

As illustrated in FIG. 1A, the package substrate 110 may have a length in the x-direction that is greater than a length of the semiconductor module 120 in the x-direction. The package substrate 110 may also have a width in the y-direction that is greater than a width of the semiconductor module 120 in the y-direction.

A package underfill layer 119 may be formed on the package substrate 110 under and around the semiconductor module 120. The package underfill layer 119 may also be formed around the C4 bumps 121. The package underfill layer 119 may thereby securely fix the semiconductor module 120 to the package substrate 110. The package underfill layer 119 may be formed of an epoxy-based polymeric material.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of polymer layers 12 and a plurality of redistribution layers 12a stacked alternately. The number of the polymer layers 12 and/or the number of redistribution layers 12a in the interposer 10 are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials.

The conductive materials may include metal such as copper, aluminum, nickel, titanium, a combination thereof or other suitable metals.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layer 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12 and may extend in the x-direction (first horizontal direction) and y-direction (second horizontal direction) on an upper surface of the polymer layers 12.

An upper passivation layer 13 may be formed on the chip-side surface of the interposer 10. The upper passivation layer 13 may include silicon oxide, silicon nitride, low-k dielectric materials such as carbon-doped oxides, extremely low-k dielectric materials such as porous carbon doped silicon dioxide, a combination thereof or other suitable material.

One or more upper bonding pads 13a may be formed in the upper passivation layer 13 on the chip-side surface of interposer 10. The upper passivation layer 13 may at least partially cover the upper bonding pads 13a. That is, the upper bonding pads 13a may be at least partially exposed on the chip-side surface of the interposer 10. The upper bonding pads 13a may be connected to the redistribution layers 12a. The upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 14 may be formed on the board-side surface of the interposer 10. The lower passivation layer 14 may also include silicon oxide, silicon nitride, low-k dielectric materials such as carbon-doped oxides, extremely low-k dielectric materials such as porous carbon doped silicon dioxide, a combination thereof or other suitable material.

The lower bonding pads 14a may be located in the lower passivation layer 14 and electrically connected to the redistribution layers 12a. The lower passivation layer 14 may at least partially cover the lower bonding pads 14a. That is, the lower bonding pads 14a may be at least partially exposed on the board-side surface of the interposer 10. The lower bonding pads 14a may also include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The semiconductor dies 140 may be attached to an upper surface of the interposer 10. The semiconductor dies 140 may include a die bonding film 145 on a frontside of the semiconductor dies 140. The die bonding film 145 may be formed, for example, of silicon dioxide, silicon nitride, silicon carbon nitride, etc. The semiconductor dies 140 may also include die bonding pads 145a in the die bonding film 145. The die bonding pads 145a may include one or more layers and may include metals, metal alloys, and/or other metal-containing compounds (e.g., Cu, Al, Mo, Co, Ru, W, TiN, TaN, WN, etc.). Other suitable metal materials may be used in the die bonding film 145 and die bonding pads 145a within the contemplated scope of disclosure.

In at least one embodiment, the semiconductor dies 140 may be attached to the interposer 10 by a hybrid bond. The hybrid bond may include a metal-metal bond between the die bonding pads 145a and the upper bonding pads 13a of the interposer 10. The hybrid bond may also include a dielectric-dielectric bond between the die bonding film 145 and the upper passivation layer 13 of the interposer 10.

Alternative structures (not shown) may be used to attach the semiconductor dies 140 to the interposer 10. In particular, the semiconductor dies 140 may be attached to the interposer 10 by a plurality of microbumps. In such an embodiment, a module underfill layer may be formed on the interposer 10, around the microbumps and under and around the semiconductor dies 140.

The plurality of semiconductor dies 140 may include a first semiconductor die 141 and second semiconductor die 142. Although the semiconductor module 120 is illustrated as including a particular number of the semiconductor dies 140 of particular sizes having a particular arrangement, the number of semiconductor dies 140, the sizes of the semiconductor dies 140 and the arrangement of the semiconductor dies 140 is not limited to any particular number, size and arrangement. In particular, the semiconductor module 120 may include any number, size and arrangement of the semiconductor dies 140.

Generally, a thickness in the z-direction of each of the semiconductor dies 140 may be substantially the same. Thus, the upper surfaces of each of the first semiconductor die 141 and second semiconductor die 142 may be substantially coplanar (e.g., formed in the same x-y plane), and referred to collectively as the semiconductor die upper surface 140a.

Each of the semiconductor dies 140 may include, for example, a singular semiconductor die structure, a system on chip (SOC) die, or a system on integrated chips (SoIC) die, and may be implemented by chip on wafer on substrate (CoWoS) technology or integrated fan-out on substrate (INFO-oS) technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., SOC die), and the second semiconductor die 142 may include an ancillary die (e. g, memory/SOC die, HBM die, etc.).

The semiconductor module 120 may also include an upper molding layer 127 formed around the semiconductor dies 140. The upper molding layer 127 may have an outer sidewall that is substantially aligned with the outer sidewall of the interposer 10. The upper molding layer 127 may also have an upper surface that is substantially uniform (e.g., flat) and substantially coplanar with the upper surface 140a of the semiconductor dies 140. The upper molding layer 127 may be formed on outer sidewalls of each of the semiconductor dies 140. The upper molding layer 127 may be bonded to the outer sidewalls of each of the semiconductor dies 140.

In at least one embodiment, the upper molding layer 127 may be formed of a curable material that may cure to form a hard, solid structure. The upper molding layer 127 may include, for example, epoxy molding compound (EMC). In at least one embodiment, the upper molding layer 127 may include a material that is substantially similar to the package underfill layer 119. In at least one embodiment, the upper molding layer 127 may include a polymeric material and in particular, an epoxy-based polymeric material. Other suitable molding materials may be used.

In at least one embodiment, the upper molding layer 127 may have a coefficient of thermal expansion (CTE) that is substantially similar to a CTE of the interposer 10. In at least one embodiment, the upper molding layer 127 may include an added material (e.g., filler material added to a polymeric material) for improving a property of the upper molding layer 127 (e.g., thermal conductivity, CTE, etc.).

The reactive interface layer 150 may include a first reactive interface layer 151 on the semiconductor module 120. In particular, the first reactive interface layer 151 may be formed on an upper surface of the upper molding layer 127 and the upper surface 140a of the semiconductor dies 140. The first reactive interface layer 151 may cover a substantial entirety of the upper surface of the semiconductor module 120. As illustrated in FIG. 1A, opposing ends of the first reactive interface layer 151 may be substantially aligned with the opposing outer sidewalls of the upper molding layer 127. The first reactive interface layer 151 may include one or more metals or metal alloys. In at least one embodiment, the first reactive interface layer 151 may include one or more of gallium, indium and nickel. In at least one embodiment, the first reactive interface layer 151 may include an alloy of gallium, indium and nickel. In at least one embodiment, the first reactive interface layer 151 may include a nickel coating. Other materials may be used for the first reactive interface layer 151.

The composite TIM layer 170 may be formed on the first reactive interface layer 151. The first reactive interface layer 151 may help enhance adhesion (e.g., adhesion between the composite TIM layer 170 and the semiconductor module 120) and reliability of the composite TIM layer 170. The composite TIM layer 170 may cover a substantial entirety of the first reactive interface layer 151. In at least one embodiment, the composite TIM layer 170 may contact an entire upper surface of the first reactive interface layer 151.

The composite TIM layer 170 may be formed on the semiconductor module 120 to dissipate of heat generated during operation of the package structure 100 (e.g., operation of the semiconductor dies 140). The composite TIM layer 170 may have a low bulk thermal impedance and high thermal conductivity. The composite TIM layer 170 may be composed of a metal material in a polymer matrix (e.g., organic polymer). The polymer may include a silicone-based polymeric material or epoxy-based polymeric material. In at least one embodiment, the polymer may include one or more of polyimide, polyethylene terephthalate, polypropylene, polycarbonate, polyethersulfone, polytetrafluoroethylene, polyurethane, etc.

In at least one embodiment, the composite TIM layer 170 may include a polymer and a liquid metal (e.g., gallium, indium, etc.) embedded in the polymer. In at least one embodiment, the composite TIM layer 170 may include a polymer and at least two filler materials having different sizes and/or shapes. In particular, the composite TIM layer 170 may include the polymer, a first filler in the polymer having a first size and a second filler in the polymer having a second size less than the first size.

In at least one embodiment, the composite TIM layer 170 may include a polymer and a metal strip filler and a granular filler in the polymer. The metal strip filler may include a metal having a melting point below 100° C. The metal strip filler may include, for example, one or more metals (liquid metals) such as indium, gallium, tin, bismuth, etc. In at least one embodiment, the granular filler may include oxide particles and/or nitride particles. The oxide particles may include metal oxide particles such as ZnOₓ, AlOₓ, AgOₓ, etc. The nitride particles may include metal nitride particles such as AlNₓ, BNₓ, etc. In at least one embodiment, the composite TIM layer 170 may be composed of a liquid metal composite composed of a polymer and a gallium-based strip filler and a ZnOₓ granular filler in the polymer (e.g., the polymer matrix). Other materials may be used in the composite TIM layer 170 within the contemplated scope of this disclosure.

In at least one embodiment, the amount of polymer in the composite TIM layer 170 (by weight) may be less than the combined amount of metal strip filler and granular filler in the composite TIM layer 170. In at least one embodiment, the amount of polymer in the composite TIM layer 170 may be in a range from 10% to 60% by weight. In at least one embodiment, the amount of metal strip filler in the composite TIM layer 170 may be in a range from 30% to 90% by weight. In at least one embodiment, the amount of granular filler in the composite TIM layer 170 may be less than the amount of metal strip filler in the composite TIM layer 170. In at least one embodiment, the amount of granular filler in the composite TIM layer 170 may be in a range from 10% to 70% by weight. Other suitable amounts of the polymer, metal strip filler and granular filler may be used.

The composite TIM layer 170 may be formed, for example, by mixing the metal strip filler and granular filler into the polymer. In particular, a liquid metal-based material (e.g., gallium, indium, etc.) may be dispersed into particles (e.g., metal strip filler particles). The particles may be coated with an oxide or nitride coating. In at least one embodiment, the particles may be oxide-coated by native oxide shell formation treatment. The coated particles may then be mixed into the polymer with appropriate amount control.

The package lid 130 may be located over the semiconductor module 120 and connected to the package substrate 110. The package lid 130 may include a package lid plate portion 130p formed on the composite TIM layer 170 over the semiconductor module 120. The package lid 130 may also include a package lid step portion 130s projecting downward from a bottom surface 135 of the package lid plate portion 130p. The package lid step portion 130s may be integrally formed with the package lid plate portion 130p. The package lid step portion 130s may have a width W130s greater than a width of the semiconductor module 120 (e.g., a distance between outer sidewalls of the upper molding layer 127). The composite TIM layer 170 may be compressed between the package lid step portion 130s and the semiconductor module 120.

The reactive interface layer 150 may include a second reactive interface layer 152 on the package lid step portion 130s. The second reactive interface layer 152 may have a width (in the x-direction) substantially the same as a width of the first reactive interface layer 151. As illustrated in FIG. 1A, the width of the second reactive interface layer 152 may be less than a width W130s of the package lid step portion 130s. In at least one embodiment, the width of the second reactive interface layer 152 may be substantially the same as the width W130s of the package lid step portion 130s. The second reactive interface layer 152 may be substantially aligned with the first reactive interface layer 151.

The second reactive interface layer 152 may contact a substantial entirety of the upper surface of the composite TIM layer 170. The second reactive interface layer 152 may enhance adhesion (e.g., adhesion between the composite TIM layer 170 and the package lid step portion 130s) and reliability of the composite TIM layer 170. As illustrated in FIG. 1A, opposing ends of the second reactive interface layer 152 may be substantially aligned with opposing sidewalls of the composite TIM layer 170. The second reactive interface layer 152 may be formed of the same materials as the first reactive interface layer 151 or different materials than the first reactive interface layer 151. The second reactive interface layer 152 may include one or more metals or metal alloys. In at least one embodiment, the second reactive interface layer 152 may include one or more of gallium, indium and nickel. In at least one embodiment, the second reactive interface layer 152 may include an alloy of gallium, indium and nickel. In at least one embodiment, the second reactive interface layer 152 may include a nickel coating. Other suitable materials may be used for the second reactive interface layer 152.

The package lid 130 may also include a package lid foot portion 130a located around an outer periphery of the package lid plate portion 130p. The package lid foot portion 130a may be integrally formed with the package lid plate portion 130p. The package lid foot portion 130a may be fixed to the package substrate 110 by an adhesive layer 160.

The package lid 130 may be formed, for example, of metal, ceramic or polymer material. In at least one embodiment, a material of the package lid 130 may include copper with a nickel coating surface (e.g., in addition to the second reactive interface layer 152). The nickel coating surface may have a thickness in a range of 1 μm to 10 μm. The package lid plate portion 130p may have a plate shape (e.g., planar shape) and be substantially parallel to an upper surface of the package substrate 110.

The package lid plate portion 130p may extend, for example, in an x-y plane in FIG. 1A. The package lid plate portion 130p may include an outer sidewall that is substantially aligned with an outer sidewall of the package lid foot portion 130a. A center of the package lid plate portion 130p may be substantially aligned in the z-direction with a center of the semiconductor module 120. An upper surface of the package lid plate portion 130p may be substantially parallel to the bottom surface 135 of the package lid plate portion 130p.

The adhesive layer 160 may be formed on the package substrate 110 near the sidewall of the semiconductor module 120. The adhesive layer 160 may bond the package lid foot portion 130a to package substrate 110. A thickness of the adhesive layer 160 may be in a range from 50 μm to 200 μm. The adhesive layer 160 may include, for example, a silicone adhesive (e.g., containing aluminum oxide, zinc oxide, resin, etc.) or an epoxy adhesive. Other suitable adhesives may be used. The adhesive layer 160 may contact the backside metal layer or the recessed upper surface of the upper molding material layer.

The package structure 100 may also include a sealant 200 formed around the composite TIM layer 170. The sealant 200 may also be formed around the first reactive interface layer 151 and the second reactive interface layer 152. In at least one embodiment, the sealant 200 may inhibit (e.g., prevent) oxidation of the composite TIM layer 170, the first reactive interface layer 151 and the second reactive interface layer 152.

As illustrated in FIG. 1A, the sealant 200 may also be formed around the package lid step portion 130s and the semiconductor module 120. The sealant 200 may also be formed around the package underfill layer 119. In at least one embodiment, a top end of the sealant 200 may contact the bottom surface 135 of the package lid plate portion 130p. In at least one embodiment, a bottom end of the sealant 200 may contact the package substrate 110. In at least one embodiment, the sealant 200 may extend continuously between the bottom surface 135 of the package lid plate portion 130p and the package substrate 110.

The sealant 200 may be composed of materials substantially similar to the materials of the upper molding layer 127 or the package underfill layer 119. In at least one embodiment, the sealant 200 may be formed of an epoxy-based polymeric material. In at least one embodiment, the sealant 200 may include one or more of a silicone sealant, a polyurethane sealant, an acrylic sealant, a fluoropolymer sealant, etc. Other suitable materials may be used in the sealant 200.

One or more surface mount devices (SMDs) 190 may also be located under the package lid 130 on the chip-side surface of package substrate 110. The SMDs 190 may be located between the package lid foot portion 130a and the semiconductor module 120 on the package substrate 110. In at least one embodiment, the SMDs 190 may be located substantially equidistant (e.g., in the x-direction) between the package lid foot portion 130a and the interposer 10 of the semiconductor module 120. The SMDs 190 may be attached to the package substrate 110 by surface mount technology (SMT). The SMDs 190 may be bonded to one or more package substrate upper bonding pads 114a and thereby electrically connected to the metal interconnect structures 114b in the package substrate upper dielectric layer 114. The SMDs 190 may, therefore, be electrically coupled to the semiconductor dies 140 through the package substrate 110 and the interposer 10.

The SMDs 190 may include, for example, integrated circuits, passive components such as resistors, capacitors and inductors, active components such as two-terminal devices, diodes and three-terminal devices, and electromechanical devices such as switches/relays, connectors and micro-motors. In at least one embodiment the SMDs 190 may include transistors (e.g., metal oxide semiconductor field effect transistors (MOSFETs)), rectifiers and voltage regulators for power management applications.

Referring again to FIG. 1B, the package lid step portion 130s may have a thickness T130s, which is less than a thickness T130p of the package lid plate portion 130p. In at least one embodiment, the thickness T130s of the package lid step portion 130s may be in a range of 10% to 50% of the thickness T130p of the package lid plate portion 130p.

A thickness T170 of the composite TIM layer 170 may be in a range of 75 μm to 450 μm. A thickness T151 of the first reactive interface layer 151 may be in a range of 5 μm to 50 μm. A thickness T152 of the second reactive interface layer 152 may be substantially the same as the thickness T151 of the first reactive interface layer 151. The thickness T152 of the second reactive interface layer 152 may also be in a range of 5 μm to 50 μm.

A bond line thickness (BLT) (e.g., a distance between the package lid 130 and the semiconductor module 120) may be equal to the thickness (T151) of the first reactive interface layer 151 plus the thickness (T170) of the composite TIM layer 170 plus the thickness (T152) of the second reactive interface layer 152. In at least one embodiment, the BLT may be in a range from 85 μm to 550 μm. In at least one embodiment, T151+T152≤70% of BLT.

Referring again to FIG. 1C, the sealant 200 may have a width W200 (first width) at the composite TIM layer 170 and at the semiconductor module 120. The width W200 of the sealant 200 may be in a range from 50 μm to 500 μm. The sealant 200 may contact a sidewall of the composite TIM layer 170 and a sidewall of the semiconductor module 120 (e.g., a sidewall of the upper bonding layer 127). The sealant 200 may also contact the end of the first reactive interface layer 151 and the end of the second reactive interface layer 152. The sealant 200 may, therefore, form a substantially air-tight seal around the composite TIM layer 170 and inhibit (e.g., prevent) oxidation of the composite TIM layer 170.

The sealant 200 may include a sealant upper portion 200u formed on a side of the package lid step portion 130s. The sealant upper portion 200u may contact an entirety of a sidewall of the package lid step portion 130s. The sealant upper portion 200u may also contact the bottom surface 135 of the package lid plate portion 130p.

The sealant upper portion 200u may have a width W200u (second width) less than the width W200 of the sealant 200. In at least one embodiment, the width W200u of the sealant upper portion 200u may be at least 10% less than the width W200 of the sealant 200. The sealant upper portion 200u may also have a thickness T200u greater than the thickness T130s of the package lid step portion 130s. In at least one embodiment, the thickness T200u of the sealant upper portion 200u may be at least 10% greater than the thickness T130s of the package lid step portion 130s.

Referring again to FIG. 1D, the sealant 200 may include a sealant bottom portion 200b on an outer portion 119o of the package underfill layer 119. A width of the sealant 200 may decrease in a direction toward the sealant bottom portion 200b. In at least one embodiment, the sealant bottom portion 200b may have a width W200b (third width) less than or equal to the width W200 of the sealant 200.

The sealant bottom portion 200b may contact a substantially entire upper surface of the outer portion 119o of the package underfill layer 119. In that case, the sealant bottom portion 200b may contact the package substrate upper passivation layer 110a. In at least one embodiment, the sealant bottom portion 200b may contact only a portion (e.g., an uppermost portion) of the outer portion 119o of the package underfill layer 119. In at least one embodiment, the width W200b of the sealant bottom portion 200b may be less than or equal to a width W119o of the outer portion 119o of the package underfill layer 119.

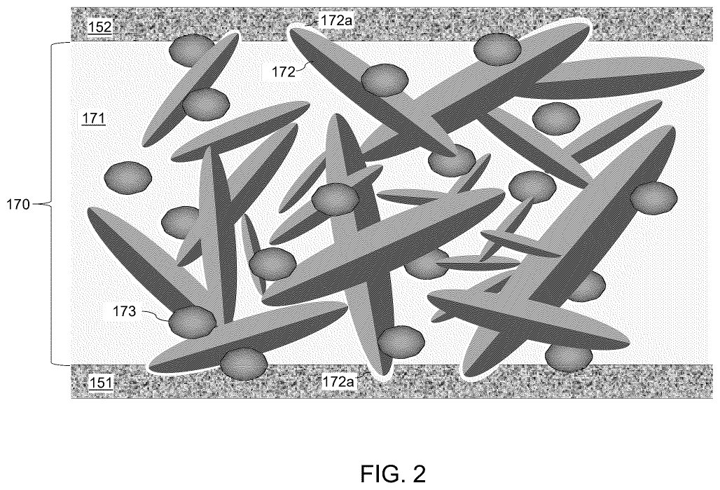

FIG. 2 is a schematic drawing of a composite TIM layer 170 in the package structure 100, according to one or more embodiments. As illustrated in FIG. 2, the composite TIM layer 170 may include a metal strip filler 172 (e.g., a metal-based filler including a liquid metal such as gallium) and a granular filler 173 embedded in the polymer 171, first reactive interface layer 151 and second reactive interface layer 152. The metal strip filler 172 may include substantially oblong-shaped particles (e.g., liquid metal particles). The granular filler 173 may include substantially spheroid-shaped particles or substantially oval-shaped particles. The granular filler 173 may have an average particle size less than average particle size of the metal strip filler. In at least one embodiment, the average particle size of the granular filler 173 may be at least 50% less than the average particle size of the metal strip filler 172.

In at least one embodiment, the metal strip filler 172 within the polymer 171 may bond to the first reactive interface layer 151 and the second reactive interface layer 152. In at least one embodiment, the metal strip filler 172 may react with the first reactive interface layer 151 (e.g., nickel-based coating layer) and the second reactive interface layer 152 (e.g., nickel-based coating layer) to form an intermetallic compound (IMC) 172a. The IMC 172a may help to bond the composite TIM layer 170 to the first reactive interface layer 151 and the second reactive interface layer 152.

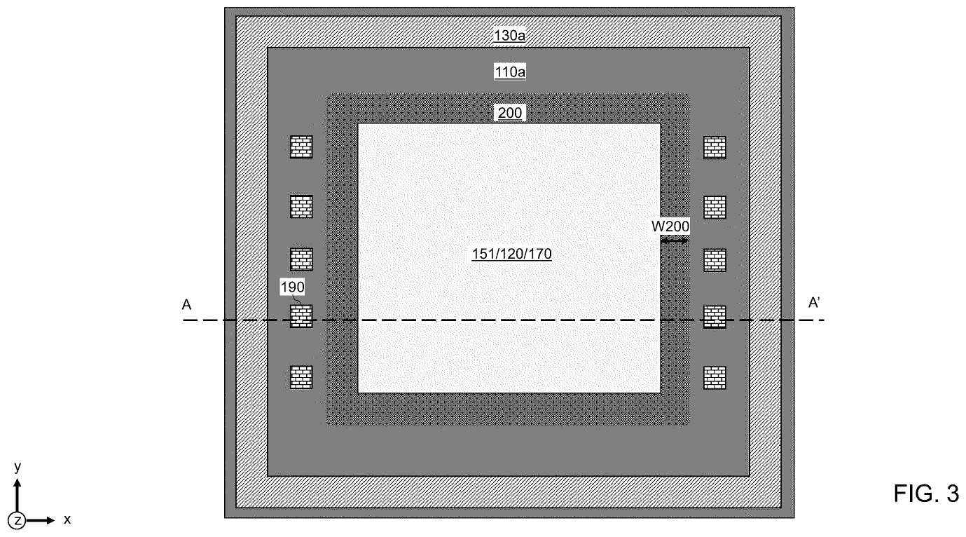

FIG. 3 is a top-down view of the package structure 100, according to one or more embodiments. The package lid plate portion 130p and package lid step portion 130s (including the second reactive interface layer 152) have been omitted in FIG. 3 for ease of understanding. The vertical cross-sectional view in FIG. 1A is along the line A-A′ in FIG. 3.

As illustrated in FIG. 3, the package substrate 110 may have a substantially square or rectangular shape. The semiconductor module 120 may have a substantially square or rectangular shape similar to the package substrate 110. The package lid foot portion 130a may be substantially frame-shaped. A width of the package lid foot portion 130a may be substantially uniform around an entirety of the package lid foot portion 130a. The package lid foot portion 130a may be formed continuously around the semiconductor module 120 and the SMDs 190. A distance between the package lid foot portion 130a and the semiconductor module 120 may be substantially uniform around the periphery of the semiconductor module 120.

The SMDs 190 may be formed on opposing sides of the semiconductor module 120. The sealant 200 may be formed around an entire periphery of the composite TIM layer 170 and an entire periphery of the semiconductor module 120. The width W200 of the sealant 200 may be substantially uniform around the entire periphery of the composite TIM layer 170 and the entire periphery of the semiconductor module 120. A distance between the sealant 200 and the SMDs may be substantially uniform on the opposing sides of the semiconductor module 120.

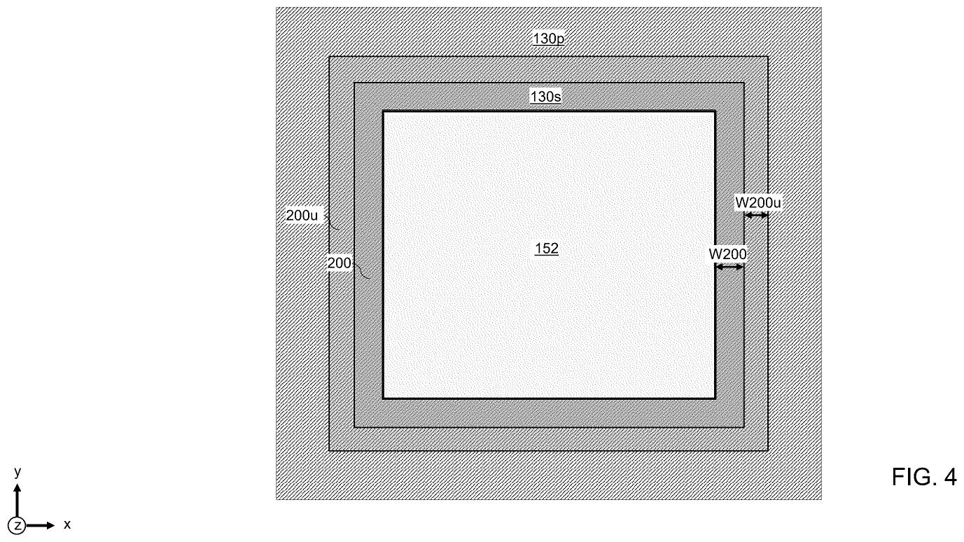

FIG. 4 is a top-down view of the package lid plate portion 100, according to one or more embodiments. A location of the sealant 200 and a location of the sealant upper portion 200u in relation to the package lid step portion 130s are indicated by shading in FIG. 4.

As illustrated in FIG. 4, a center of the second reactive interface layer 152 may be substantially aligned with a center of the package lid step portion 130s. A shape of the second reactive interface layer 152 may be substantially the same as the shape of the first reactive interface layer 151 (see FIG. 3). Therefore, an entire outer edge of the second reactive interface layer 152 may be substantially coextensive with an entire outer edge of the first reactive interface layer 151.

Further, a shape of the package lid step portion 130s may be substantially the same as a shape of the second reactive interface layer 152. An outer sidewall of the sealant 200 may be substantially aligned with an outer sidewall of the package lid step portion 130s around an entire periphery of the package lid step portion 130s. Further, the width W200u of the sealant upper portion 200u may be substantially uniform around the entire periphery of the package lid step portion 130s.

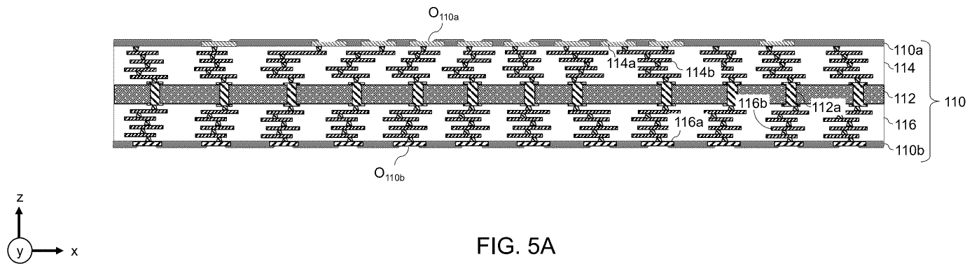

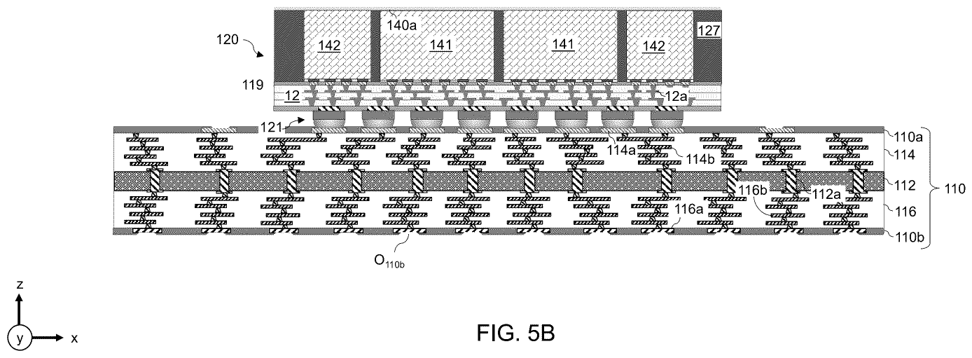

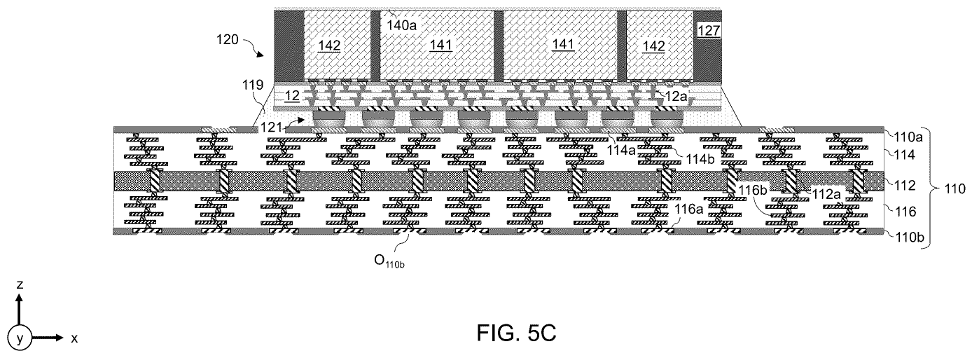

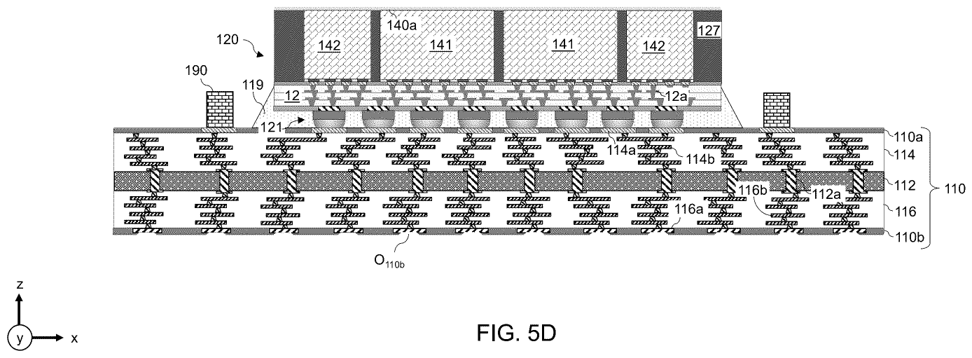

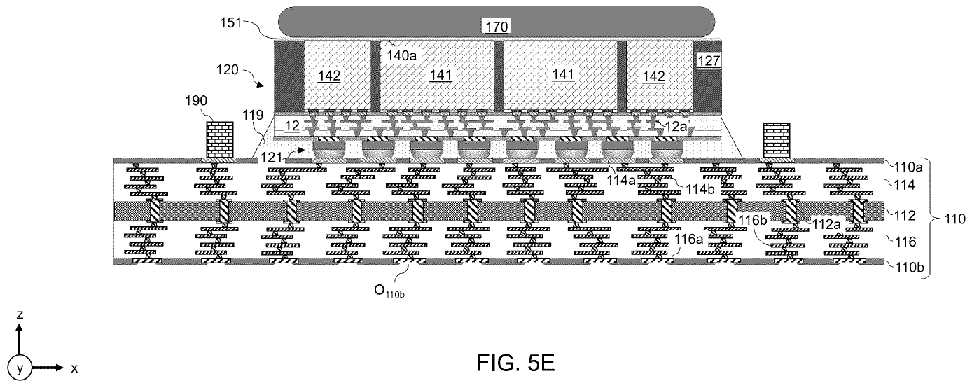

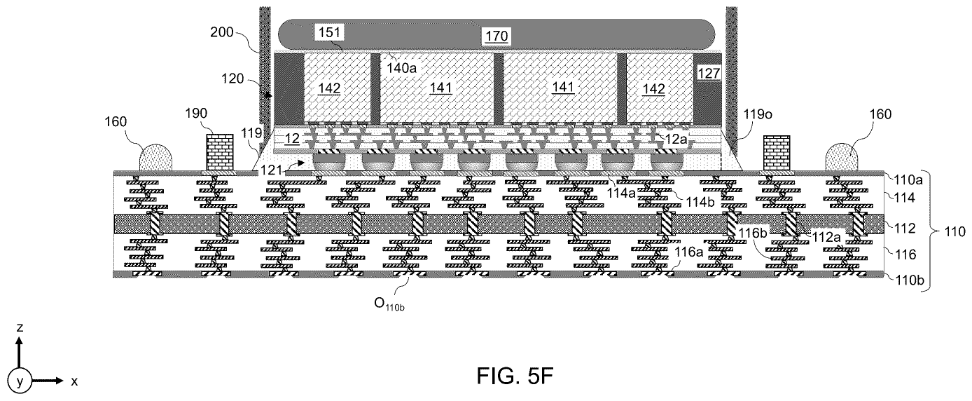

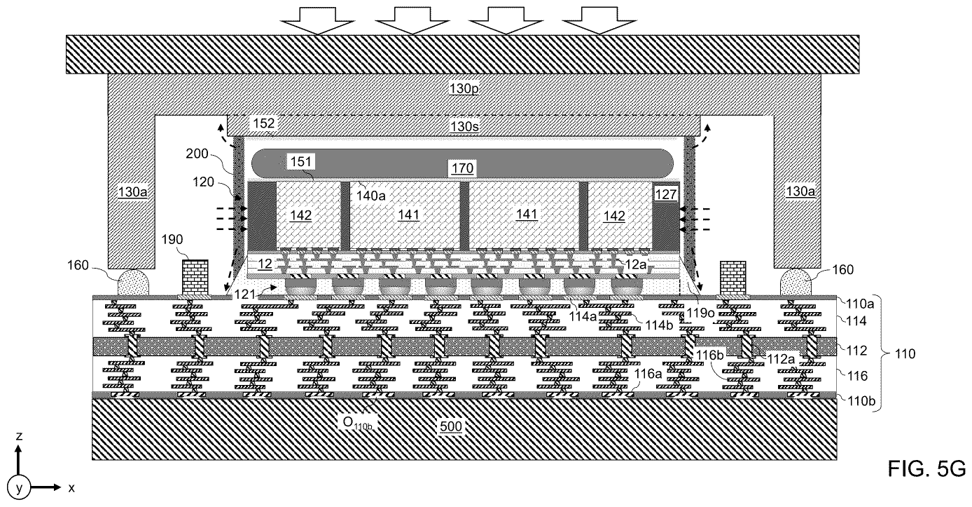

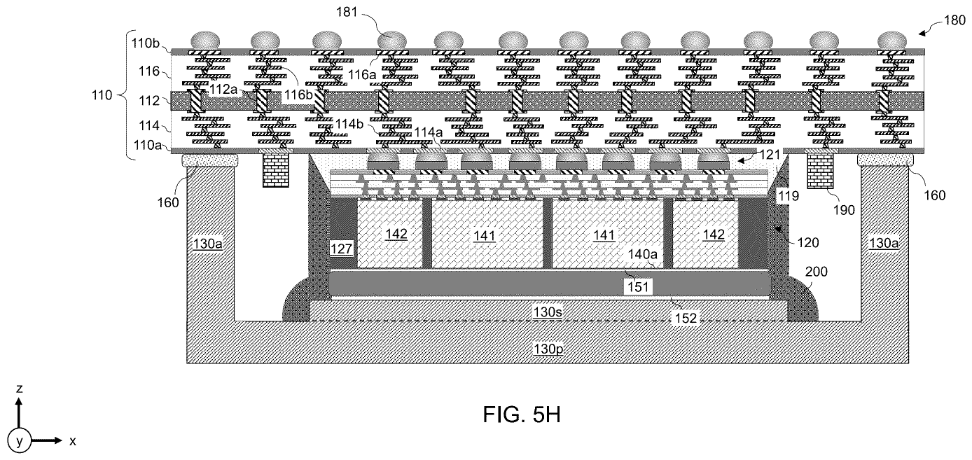

FIGS. 5A-5H illustrate various intermediate structures in a method of forming the package structure 100 according to one or more embodiments. FIG. 5A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a may include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively.

Openings O₁₁₀ₐ may then be formed in the package substrate upper passivation layer 110a so as to expose the upper surface of the package substrate upper bonding pads 114a. Openings O_{110b} may be formed in the package substrate lower passivation layer 110b to expose an upper surface of the package substrate lower bonding pads 116a. The openings O₁₁₀ₐ and the openings O_{110b} may be formed, for example, by using a photolithographic process. In at least one embodiment, the openings O₁₁₀ₐ and the openings O_{110b} may be formed in separate photolithographic processes.

The photolithographic process (e.g., processes) used to form the openings O^{110a} may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O_{110b} may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper passivation layer 110a and the openings O_{110b} are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 5B illustrates a vertical cross-sectional view of an intermediate structure in which the semiconductor module 120 may be mounted on the package substrate 110, according to one or more embodiments. The semiconductor module 120 may be mounted on the package substrate 110, for example, by a flip chip bonding (FCB) process. The semiconductor die module 120 may be positioned over the package substrate 110, for example, by an electromechanical pick-and-place (PNP) machine.

The C4 bumps 121 on the semiconductor die module 121 may then be lowered onto the package substrate upper bonding pads 114a of the package substrate 110 and heated in order to collapse the C4 bumps 121 and bond the C4 bumps 121 to the package substrate upper bonding pads 114a.

FIG. 5C illustrates a vertical cross-sectional view of an intermediate structure in which the package underfill layer 119 may be formed on the package substrate 110 according to one or more embodiments. The package underfill layer 119 may be formed of an epoxy-based polymeric material. As illustrated in FIG. 5C, the package underfill layer 119 may be formed (e.g., injected) under and around the semiconductor module 120 and the C4 bumps 121 to the package substrate 110. The package underfill layer 119 may then be cured, for example, in a box oven for duration in a range from 60 minutes to 120 minutes at a temperature in a range from 120° C. to 180° C. to provide the package underfill layer 119 with a sufficient stiffness and mechanical strength.

FIG. 5D illustrates a vertical cross-sectional view of an intermediate structure in which the SMDs 190 may be mounted on the package substrate 110, according to one or more embodiments. The SMDs 190 may include bonding pads (not shown) that may be bonded to the package substrate upper bonding pads 114a of the package substrate 110. The SMDs 190 may be mounted by surface mount technology. A solder paste (e.g., a mixture of tiny solder balls (e.g., SnAgCu) and flux) may be applied to the package substrate upper bonding pads 114a by a stencil or screen. An electro-mechanical pick-and-place (PnP) machine may then be used to pick up the SMDs 190 (e.g., resistors, capacitors, ICs) and accurately place them onto the solder paste on the package substrate upper bonding pads 114a. The package substrate 110 with the placed SMDs 190 may then be passed through a reflow oven, causing the solder paste to melt and reflows and forming a solder joint between the SMDs 190 and the package substrate upper bonding pads 114a. An adhesive (not shown) substantially similar to the adhesive layer 160 may optionally be used (in addition to the solder joint) to attach the SMDs 190 to the package substrate 110.

FIG. 5E illustrates a vertical cross-sectional view of an intermediate structure in which the composite TIM layer 170 may be formed on the semiconductor module 120 according to one or more embodiments. In at least one embodiment, the composite TIM layer 170 may be placed in a solid or semi-solid state onto the upper surface of the first reactive interface layer 151 on the semiconductor module 120. In at least one embodiment, the composite TIM layer 170 may be dispensed as a liquid in an uncured state onto the upper surface of the first reactive interface layer 151 on the semiconductor module 120. The uncured composite TIM layer 170 may be dispensed, for example, using an electromechanical dispenser (e.g., pump-driven dispenser) that dispenses a metered amount of the uncured composite TIM layer 170. Other suitable methods of dispensing the composite TIM layer 170 may be used.

FIG. 5F illustrates a vertical cross-sectional view of an intermediate structure after applying the sealant 200 and adhesive layer 160 according to one or more embodiments. The sealant 200 and adhesive layer 160 may be applied in the same process step or different process steps.

The sealant 200 may be placed in a solid or semi-solid state around the semiconductor module 120 onto an upper surface of the package underfill layer 119. In at least one embodiment, the sealant 200 may be dispensed onto the upper surface of the package underfill layer 119 as a liquid in an uncured state. The sealant 200 may be applied/dispensed in a central portion of the outer portion 119o of the package underfill layer 119. The sealant 200 may be dispensed, for example, using an electromechanical dispenser (e.g., pump-driven dispenser) that dispenses a metered amount of the uncured sealant 200. In at least one embodiment, the sealant 200 may be dispensed using an auger valve dispensing tool.

A width (e.g., in the x-direction) of the sealant 200 applied/dispensed on the upper surface of the package underfill layer 119 may be less than the width W119o of the outer portion 119o of the package underfill layer 119 (see FIG. 1D). A height of the sealant 200 applied/dispensed on the upper surface of the package underfill layer 119 may be greater than a height of the first reactive interface layer 151. In at least one embodiment, the height of the uncured sealant 200 applied/dispensed on the upper surface of the package underfill layer 119 may be greater than a height of the composite TIM layer 170. Other suitable methods of dispensing the sealant 200 may be used.

The adhesive layer 160 may also be dispensed using an electromechanical dispenser (e.g., pump-driven dispenser, automated dispensing tool) that dispenses a metered amount of adhesive material onto the package substrate 110. The dispenser may dispense the adhesive layer 160 in a frame shape around the semiconductor module 120. At the time of application, the adhesive layer 160 may be sufficiently rigid so as to form a semi-solid bead on the surface of the package substrate 110. In at least one embodiment, a viscosity of each the adhesive layer 160 at the time of application may be 50,000 centipoise (cp) or greater. The shape of the semi-solid bead may remain substantially unchanged between the time of application by the dispensing tool and the later time of attaching the package lid 130. The location of the frame shape of the adhesive layer 160 may correspond to a location of the package lid foot portion 130a of the package lid 130 (e.g., see FIG. 1A). A pressing of the package lid 130 onto the adhesive layer 160 may deform the adhesive layer 160.

FIG. 5G illustrates a vertical cross-sectional view of an intermediate structure in which the package lid 130 may be attached to (e.g., mounted on) the package substrate 110 according to one or more embodiments. The package substrate 110 may be placed on a rigid surface such as an underboard support 500. The package lid 130 may then be positioned over the semiconductor module 120. In at least one embodiment, the package lid 130 may be positioned over the semiconductor module 120 by an electromechanical pick-and-place (PNP) machine.

The package lid 130 may be positioned over the semiconductor module 120 such that the center of the package lid step portion 130s is substantially aligned with the center of the semiconductor module 120. The package lid 130 may also be positioned over the semiconductor module 120 such that the package lid step portion 130s is located over the sealant 200. The package lid 130 may also be positioned over the semiconductor module 120 such that the package lid foot portion 130a of the package lid 130 may be substantially aligned with the adhesive layer 160 (e.g., frame-shaped bead of adhesive material) formed on the package substrate 110.

The package lid 130 may then be lowered down over the semiconductor module 120 and onto the package substrate 110. A downward pressing force may then be applied to the package lid plate portion 130p. The downward pressing force may cause the package lid step portion 130s to compress and deform the composite TIM layer 170 and the sealant 200. The downward pressing force may also cause the package lid foot portion 130a to compress and deform and the adhesive layer 160.

In particular, the composite TIM layer 170 may be deformed by the downward pressing force so as to flow over a substantial entirety of the first reactive interface layer 151. In at least one embodiment, the composite TIM layer 170 may be deformed so as to substantially fill a space between the first reactive interface layer 151 and the second reactive interface layer 152. The sealant 200 may be deformed by the downward pressing force so as to flow (shown by directional arrows) in a direction around the package lid step portion 130s. The sealant 200 may also be deformed by the downward pressing force so as to flow in a direction toward to the sidewall of the semiconductor module 120 and in direction along the surface of the outer portion 119o of the package underfill layer 119. In at least one embodiment, the sealant 200 may be deformed so as to substantially surround the package lid step portion 130s, the composite TIM layer 170 and the semiconductor module 120.

The package lid 130 may then be clamped to the package substrate 110 for a period to allow the composite TIM layer 170, the sealant 200 and the adhesive layer 160 to cure (e.g., snap cure). The sealant 200 may cure to form a substantially air-tight seal around the composite TIM layer 170. The adhesive layer 160 may cure to form a secure bond between the package substrate 110 and the package lid 130. The clamping of the package lid 130 to the package substrate 110 may be performed, for example, by using a heat clamp module. The heat clamp module may apply a uniform force across the upper surface of the package lid plate portion 130p. In one or more embodiments, the heat clamp module may apply the downward pressing force to the package lid plate portion 130p.

FIG. 5H illustrates a vertical cross-sectional view of an intermediate structure in which the BGA 180 including a plurality of solder balls 181 may be formed on the package substrate 110 according to one or more embodiments. The plurality of solder balls 181 may be formed on the package substrate lower bonding pads 116a through the openings O110b in the package substrate lower passivation layer 110b. The solder balls 181 may be formed, for example, by an electroplating process. The solder balls 181 may be formed, for example, so as to be located under the package lid foot portion 130a and under the semiconductor module 120 and therebetween. The BGA 180 including the plurality of solder balls 181 may allow the package structure 100 to be securely mounted (e.g., by surface mount technology (SMT)) on a substrate such as a printed circuit board and electrically coupled to the substrate. Formation of the solder balls 181 may complete the formation of the package structure 100.

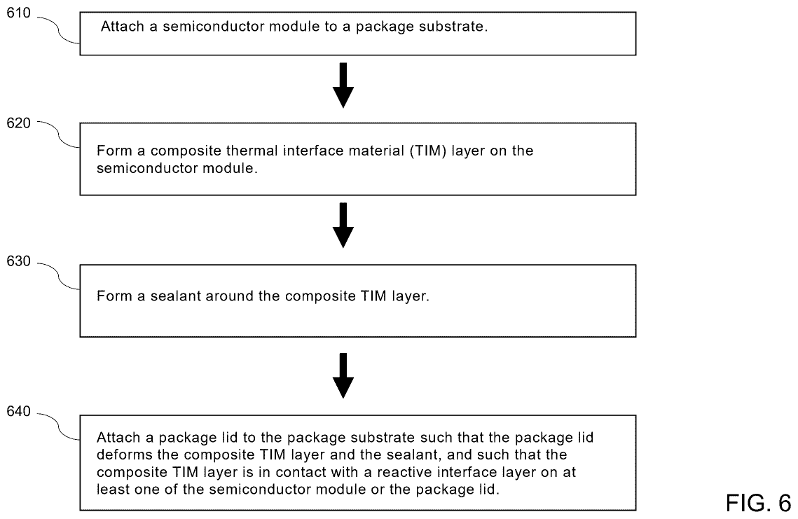

FIG. 6 is a flow chart illustrating a method of forming the package structure 100 according to one or more embodiments. Step 610 includes attaching a semiconductor module to a package substrate. Step 620 includes forming a composite thermal interface material (TIM) layer on the semiconductor module. Step 630 includes forming a sealant around the composite TIM layer. Step 640 includes attaching a package lid to the package substrate such that the package lid deforms the composite TIM layer and the sealant, and such that the composite TIM layer is in contact with a reactive interface layer on at least one of the semiconductor module or the package lid.

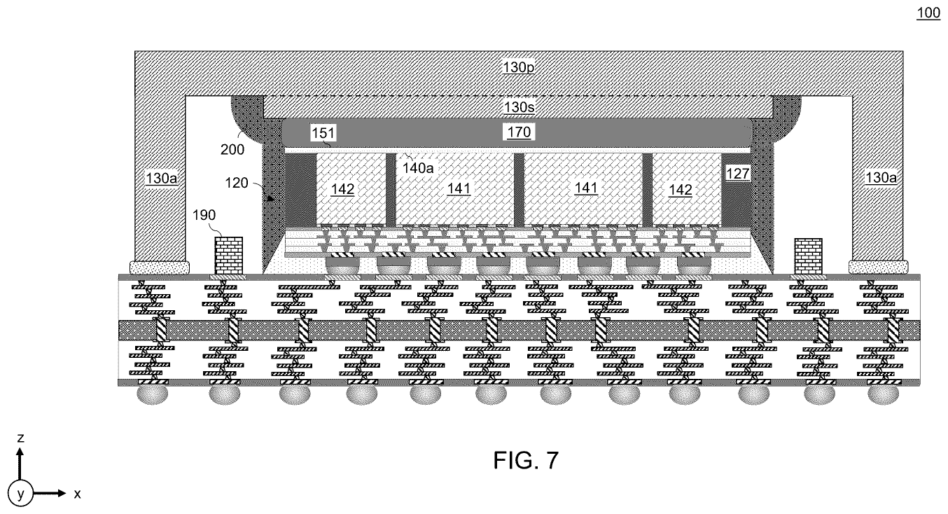

FIG. 7 is a vertical cross-sectional view of a package structure 100 having a first alternative design, according to one or more embodiments. As illustrated in FIG. 7, in the first alternative design, the package structure 100 may include the first reactive interface layer 151. However, the second reactive interface layer 152 may be omitted in the package structure 100 having the first alternative design. Thus, in the first alternative design, the package lid step portion 130s may directly contact the composite TIM layer 170. With the first alternative design, the process steps used to manufacture the package structure 100 may be reduced as compared to the package structure in FIGS. 1A-1D.

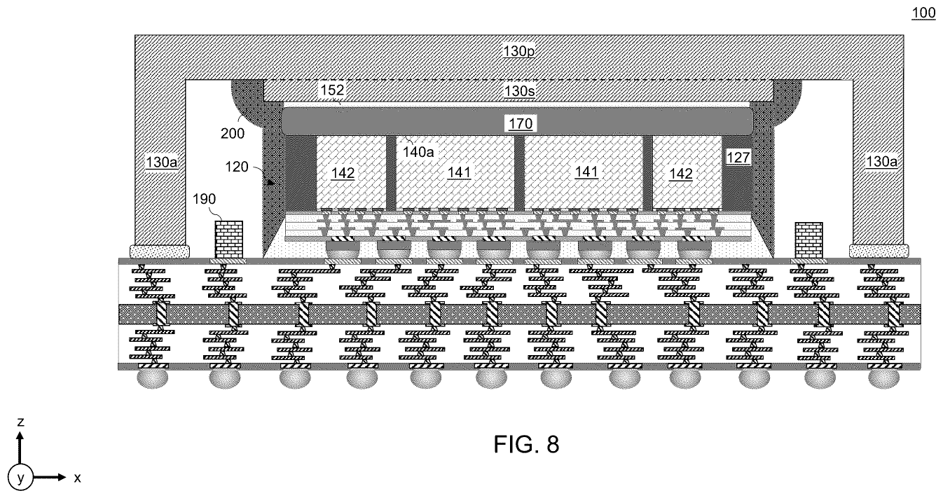

FIG. 8 is a vertical cross-sectional view of a package structure 100 having a second alternative design, according to one or more embodiments. As illustrated in FIG. 8, in the second alternative design, the package structure 100 may include the second reactive interface layer 152. However, the first reactive interface layer 151 may be omitted in the package structure 100 having the second alternative design. Thus, in the second alternative design, the composite TIM layer 170 may be formed directly on the upper surface 140a of the semiconductor dies 140 and the upper surface of the upper molding layer 127. With the second alternative design, the process steps used to manufacture the package structure 100 may be reduced as compared to the package structure in FIGS. 1A-1D.

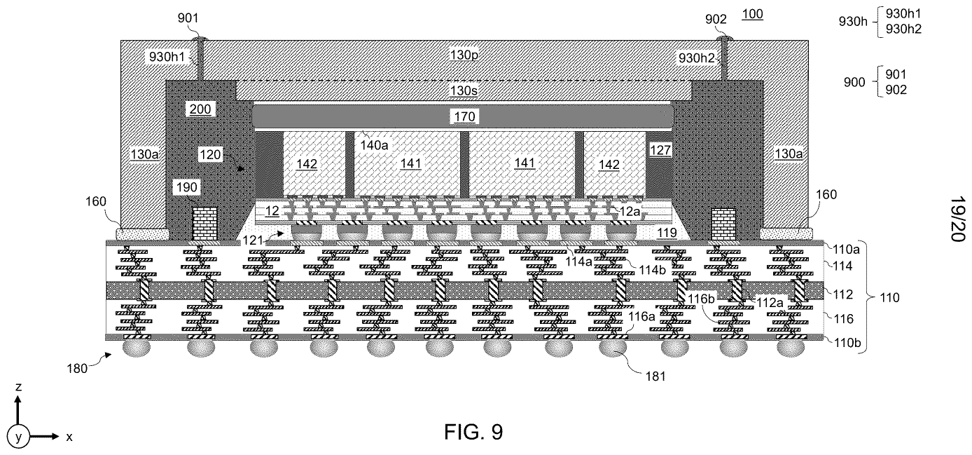

FIG. 9 is a vertical cross-sectional view of a package structure 100 having a third alternative design, according to one or more embodiments. As illustrated in FIG. 9, in the third alternative design, the package lid plate portion 130p may include one or more openings 930h. The openings 930h may allow access to an interior of the package structure 100 after the package lid 130 is attached to the package substrate 110. The package structure 100 may also include one or more plugs 900 that fill the openings 930h, respectively. The plugs 900 may be composed, for example, of the same material as the sealant 200.

As illustrated in FIG. 9, the openings 930h may include a first opening 930h1 on a first side of the semiconductor module 120 and a second opening 930h2 on a second side of the semiconductor module 120 opposite the first side. The plugs 900 may include a first plug 901 in the first opening 930h1 and a second plug 902 in the second opening 930h2. In the third alternative design, the sealant 200 may substantially fill an interior of the package structure 100. The sealant 200 may, therefore, effectively form a substantially air-tight seal around the composite TIM layer 170.

The package structure 100 having the third alternative design may be made by injecting the sealant 200 into the interior of the package structure 100 through one or more of the openings 930h. Thus, the method of making the package structure 100 having the third alternative design may differ from the method of making the package structure 100 described above in FIGS. 5A-5H by forming the sealant 200 after attaching the package lid 130 to the package substrate 110 instead of before attaching the package lid 130 to the package substrate 110. In particular, the sealant 200 may be injected into one or more of the openings 930h while a vacuum is pulled on the interior of the package structure through one or more of the openings 930h.

Thus, for example, the sealant 200 may be formed in the package structure 100 by injecting the sealant 200 (e.g., in an uncured state) into the package through the first opening 930h1, while pulling a vacuum on the interior of the package structure 100 through the second opening 930h2. The injecting of the sealant 200 may be ended, for example, when the sealant 200 becomes visible in the second opening 930h2.

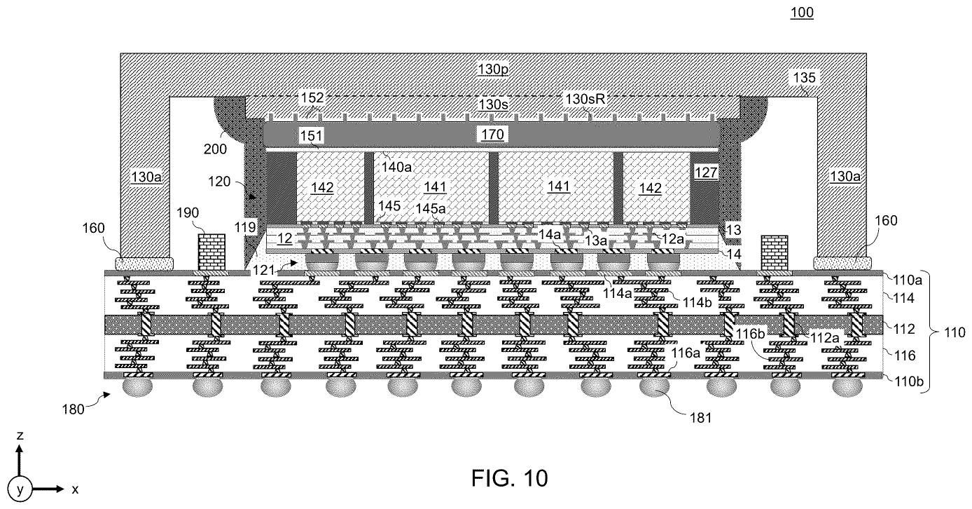

FIG. 10 is a vertical cross-sectional view of a package structure 100 having a fourth alternative design, according to one or more embodiments. As illustrated in FIG. 10, in the fourth alternative design, the package lid step portion 130s may include a plurality of recesses 130sR. In at least one embodiment, the plurality of recesses 130sR may be formed in a plurality of rows and columns constituting a two dimensional array. The second reactive interface layer 152 may be formed in the plurality of recesses 130sR.

In making the package structure 100 having the fourth alternative design, when the package lid step portion 130s is pressed onto to the composite TIM layer 170, the composite TIM layer 170 may be forced into the plurality of recesses 130sR. In at least one embodiment, the composite TIM layer 170 may substantially fill the plurality of recesses 130sR. With the fourth alternative design of the package structure 100, the surface area of the second reactive interface layer 152 may be significantly increased. Therefore, an area of interface between the composite TIM layer 170 and the second reactive interface layer 152 may be significantly increased, and adhesion between the package lid step portion 130s and the composite TIM layer 170 may be significantly increased.

Referring to FIGS. 1A-10, a package structure 100 may include a package substrate 110, a semiconductor module 120 on the package substrate 110, a composite thermal interface material (TIM) layer 170 including liquid metal in a polymer matrix on the semiconductor module 120, a package lid 130 on the composite TIM layer 170 and attached to the package substrate 110, and a reactive interface layer 150 in contact with the composite TIM layer 170 on at least one of the semiconductor module 120 or the package lid 130.

In one embodiment, the composite TIM layer 170 further may include a granular filler in the polymer matrix. In one embodiment, the granular filler may include a metal oxide granular filler. In one embodiment, the reactive interface layer 150 may be on the semiconductor module 120 and the package lid 130. In one embodiment, the reactive interface layer 150 may include at least one of Ga, In or Ni. In one embodiment, a combined thickness of the reactive interface layer 150 on the semiconductor module 120 and the reactive interface layer 150 on the package lid 130 may be less than or equal to 70% of the TIM layer 170 bond line thickness. In one embodiment, the package lid 130 may include a package lid step portion 130s and the reactive interface layer 150 may be on the package lid step portion 130s. In one embodiment, the package structure 100 may further include a sealant 200 around the semiconductor module 120, the composite TIM layer 170 and the package lid step portion 130s. In one embodiment, the sealant 200 may have a first width W200 at the composite TIM layer 170 and a second width W200u less than the first width W200 at the package lid step portion 130s. In one embodiment, the package structure 100 may further include a package underfill layer 119 on the package substrate 110 and under and around the semiconductor module 120, wherein the sealant 200 may be on the package underfill layer 119. In one embodiment, an outer sidewall of the sealant 200 may be substantially aligned with an outer periphery of the package underfill layer 119. In one embodiment, the sealant 200 may have a first width W200 at the composite TIM layer 170 and a third width W200b less than or equal to the first width W200 at the package underfill layer 119. In one embodiment, the third width W200b of the sealant 200 may be less than or equal to a width W119o of an outer portion 119o of the package underfill layer 119. In one embodiment, the package lid 130 may further include a bottom surface 135, the package lid step portion 130s may protrude from the bottom surface 135, and a thickness T200u of the sealant 200 in contact with the bottom surface 135 of the package lid 130 may be greater than a thickness T130s of the package lid step portion 130s.

Referring again to FIGS. 1A-10, a method of forming a package structure 100 may include attaching a semiconductor module 120 to a package substrate 110, forming a composite thermal interface material (TIM) layer 170 on the semiconductor module 120, forming a sealant 200 around the composite TIM layer 170, and attaching a package lid 130 to the package substrate 110 such that the package lid 130 deforms the composite TIM layer 170 and the sealant 200, and such that the composite TIM layer 170 may be in contact with a reactive interface layer 150 on at least one of the semiconductor module 120 or the package lid 130.

In one embodiment, the method may further include forming a package underfill layer 119 on the package substrate 110 under and around the semiconductor module 120, wherein the forming of the sealant 200 may include forming the sealant 200 on the package underfill layer 119 and around the semiconductor module 120. In one embodiment, the attaching of the package lid 130 to the package substrate 110 may include deforming the sealant 200 with the package lid 130 such that the sealant 200 contacts a sidewall of the semiconductor module 120 and a bottom surface of the package lid 130. In one embodiment, the attaching of the package lid 130 to the package substrate 110 may include deforming the sealant 200 with the package lid 130 such that an outer sidewall of the sealant 200 may be substantially aligned with an outer periphery of the package underfill layer 119. In one embodiment, the package lid 130 may include a package lid step portion 130s and the attaching of the package lid 130 to the package substrate 110 may include deforming the sealant 200 with the package lid step portion 130s such that the sealant 200 may be formed around the package lid step portion 130s.

Referring again to FIGS. 1A-10, a package structure 100 may include a package substrate 110, a semiconductor module 120 including a first reactive interface layer 151 on the package substrate 110, a package lid 130 including a second reactive interface layer 152 on the semiconductor module 120, a composite thermal interface material (TIM) layer 170 between the package lid 130 and the semiconductor module 120 and contacting the first reactive interface layer 151 and the second reactive interface layer 152, wherein the composite TIM layer 170 includes a polymer matrix 171 and a metal-based filler 172 and a granular filler 173 having a size less than a size of the metal-based filler 172 in the polymer matrix 171, and a sealant 200 formed around the composite TIM layer 170, contacting an outer sidewall of the composite TIM layer 170 and configured to form an air-tight seal around the composite TIM layer 170.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a semiconductor module on the package substrate;
a composite thermal interface material (TIM) layer including liquid metal in a polymer matrix on the semiconductor module;
a package lid on the composite TIM layer and attached to the package substrate; and
a reactive interface layer in contact with the composite TIM layer on at least one of the semiconductor module or the package lid.

2. The package structure of claim 1, wherein the composite TIM layer further comprises a granular filler in the polymer matrix.

3. The package structure of claim 2, wherein the granular filler comprises a metal oxide granular filler.

4. The package structure of claim 1, wherein the reactive interface layer is located on the semiconductor module and the package lid.

5. The package structure of claim 4, wherein the reactive interface layer comprises at least one of Ga, In or Ni.

6. The package structure of claim 4, wherein a combined thickness of the reactive interface layer on the semiconductor module and the reactive interface layer on the package lid is less than or equal to 70% of a TIM layer bond line thickness.

7. The package structure of claim 4, wherein the package lid comprises a package lid step portion and the reactive interface layer is on the package lid step portion.

8. The package structure of claim 7, further comprising:
a sealant around the semiconductor module, the composite TIM layer and the package lid step portion.

9. The package structure of claim 8, wherein the sealant has a first width at the composite TIM layer and a second width less than the first width at the package lid step portion.

10. The package structure of claim 8, further comprising:
a package underfill layer on the package substrate and under and around the semiconductor module, wherein the sealant is on the package underfill layer.

11. The package structure of claim 10, wherein an outer sidewall of the sealant is substantially aligned with an outer periphery of the package underfill layer.

12. The package structure of claim 10, wherein the sealant has a first width at the composite TIM layer and a third width less than or equal to the first width at the package underfill layer.

13. The package structure of claim 12, wherein the third width of the sealant is less than or equal to a width of an outer portion of the package underfill layer.

14. The package structure of claim 8, wherein the package lid further comprises a bottom surface, the package lid step portion protrudes from the bottom surface, and a thickness of the sealant in contact with the bottom surface of the package lid is greater than a thickness of the package lid step portion.

15. A method of forming a package structure, the method comprising:
attaching a semiconductor module to a package substrate;
forming a composite thermal interface material (TIM) layer on the semiconductor module;
forming a sealant around the composite TIM layer; and
attaching a package lid to the package substrate such that the package lid deforms the composite TIM layer and the sealant, and such that the composite TIM layer is in contact with a reactive interface layer on at least one of the semiconductor module or the package lid.

16. The method of claim 15, further comprising:
forming a package underfill layer on the package substrate under and around the semiconductor module, wherein the forming of the sealant comprises forming the sealant on the package underfill layer and around the semiconductor module.

17. The method of claim 15, wherein the attaching of the package lid to the package substrate comprises deforming the sealant with the package lid such that the sealant contacts a sidewall of the semiconductor module and a bottom surface of the package lid.

18. The method of claim 15, wherein the attaching of the package lid to the package substrate comprises deforming the sealant with the package lid such that an outer sidewall of the sealant is substantially aligned with an outer periphery of a package underfill layer.

19. The method of claim 15, wherein the package lid comprises a package lid step portion and the attaching of the package lid to the package substrate comprises deforming the sealant with the package lid step portion such that the sealant is formed around the package lid step portion.

20. A package structure, comprising:
a package substrate;
a semiconductor module including a first reactive interface layer on the package substrate;
a package lid including a second reactive interface layer on the semiconductor module;
a composite thermal interface material (TIM) layer between the package lid and the semiconductor module and contacting the first reactive interface layer and the second reactive interface layer, wherein the composite TIM layer includes a polymer matrix and a metal-based filler and a granular filler having a size less than a size of the metal-based filler in the polymer matrix; and
a sealant formed around the composite TIM layer, contacting an outer sidewall of the composite TIM layer and configured to form an air-tight seal around the composite TIM layer.
